(19) United States
(12) Patent Application Publication
(10) Pub. No.: US 2014/0003017 A1
(43) Pub. Date: Jan. 2, 2014

(54) ELECTRONIC COMPONENT AND MANUFACTURING METHOD THEREFOR

(71) Applicant: Murata Manufacturing Co., Ltd., Nagaokakyo-shi (JP)

(72) Inventors: Seiji KAI, Nagaokakyo-shi (JP); Shintaro NAKATANI, Nagaokakyo-shi (JP); Mitsuyoshi HIRA, Nagaokakyo-shi (JP); Takao MUKAI, Nagaokakyo-shi (JP); Hisashi YAMAZAKI, Nagaokakyo-shi (JP)

(73) Assignee: Murata Manufacturing Co., Ltd., Nagaokakyo-shi (JP)

(21) Appl. No.: 14/016,415

(22) Filed: Sep. 3, 2013

Related U.S. Application Data
(63) Continuation of application No. PCT/JP2011/079790, filed on Dec. 22, 2011.

(30) Foreign Application Priority Data
Mar. 28, 2011 (JP) 2011-069305

(51) Int. Cl. H05K 1/18; H03H 3/08

(52) U.S. Cl. CPC H05K 1/182; H03H 3/08
USPC 361/783; 29/829; 29/842; 29/852; 29/831

(57) ABSTRACT

An electronic component includes a frame-shaped supporting body including a heat-curable resin and surrounding a functional unit on one main surface of a substrate and so as to be separated from a periphery of the substrate on an inner side and in which a lid member is fixed to the supporting body such that an opening of the frame-shaped supporting body is sealed. The frame-shaped supporting body includes a frame-shaped supporting body main body, a first protrusion that protrudes toward an inside from the supporting body main body and a second protrusion that protrudes toward an outside from the supporting body main body at a portion where the supporting body main body and the first protrusion are continuous with each other.

### BACKGROUND OF THE INVENTION

1. Field of the Invention

The present invention relates to an electronic component in which a substrate and a lid member are joined to each other via a frame-shaped supporting body including a heat-curable resin, and relates to a manufacturing method therefor.

2. Description of the Related Art

In a surface acoustic wave filter device, for example, a package structure having a cavity is adopted, in which a surface acoustic wave filter element faces the cavity. Consequently, in order to make progress in size reduction of such a device, development of wafer level chip size packaging (WLCSP) has been progressing. In WLCSP, the size of the planar shape of a package is the same as that of a surface acoustic wave element chip.

For example, in Japanese Unexamined Patent Application Publication No. 2002-532934, an example of this kind of surface acoustic wave device is disclosed. As illustrated in FIG. 9, a surface acoustic wave device 1001 described in Japanese Unexamined Patent Application Publication No. 2002-532934 includes a plate-shaped surface acoustic wave element 1002. The surface acoustic wave element 1002 includes a piezoelectric substrate 1003. Functional units 1004 including IDT electrodes are formed on the upper surface of the piezoelectric substrate 1003. A rectangular frame-shaped supporting body 1005 is formed on the upper surface of the surface acoustic wave element 1002. The supporting body 1005 is arranged so as to surround the functional units 1004. A lid member 1006 is fixed to the top of the supporting body 1005 such that a cavity that the functional units 1004 face is sealed.

Penetrating electrodes 1007 are formed so as to penetrate through the frame-shaped supporting body 1005 and the lid member 1006. Outer terminals 1008 are formed on the upper ends of the penetrating electrodes 1007.

In the surface acoustic wave device 1001, the outer peripheries of the supporting body 1005 and the lid member 1006 have the same dimensions as the outer periphery of the surface acoustic wave element 1002. Therefore, a reduction in size can be achieved.

On the other hand, in the surface acoustic wave device 1001, the wider the cavity which the functional units 1004 face becomes, the greater the number of functional units that can be arranged in the cavity. If the size of the cavity can be increased, size reduction of the surface acoustic wave device 1001 can also progress. In order to increase the area of the planar shape of the cavity, the width of the frame-shaped supporting body 1005 may be decreased. However, the frame-shaped supporting body 1005 needs to have a certain width in order to allow the penetrating electrodes 1007 to be formed. In this case, the area of the cavity is decreased. In addition, if the width of the supporting body 1005 is decreased, the cavity cannot be sufficiently tightly sealed. Accordingly, in cases such as where there is a change in temperature, there is a risk of leak defects occurring. Consequently, there has been a problem in that the environmental resistance has been degraded.

### SUMMARY OF THE INVENTION

Preferred embodiments of the present invention provide an electronic component including a package structure including a cavity, in which progress can be made in size reduction, is capable of suppressing or preventing leak defects and is therefore excellent in terms of environmental resistance.

An electronic component according to a preferred embodiment of the present invention includes a substrate, a functional unit located on one main surface of the substrate, a frame-shaped supporting body including a heat-curable resin that is arranged on the one main surface of the substrate so as to surround the functional unit and so as to be separated from the periphery of the substrate on the inner side, and a lid member that is fixed to the supporting body so as to seal an opening of the supporting body. In the electronic component according to a preferred embodiment of the present invention, the frame-shaped supporting body includes a frame-shaped supporting body main body, a first protrusion that protrudes toward the inside from the supporting body main body and a second protrusion that is provided at a portion in which the supporting body main body and the first protrusion are continuous with each other so as to protrude toward the outside from the supporting body main body.

In a certain specific aspect of the electronic component according to a preferred embodiment of the present invention, the electronic component further includes a penetrating electrode that is electrically connected to the functional unit and is arranged so as to penetrate through the first protrusion and the lid member, and further includes an outer terminal that is connected to an upper portion of the penetrating electrode. In this case, it is possible to electrically connect the functional unit to the outer terminal via the penetrating electrode by utilizing the first protrusion. Therefore, progress can be made in size reduction. In addition, by selecting the area and shape of the first protrusion provided so as to be continuous with the frame-shaped supporting body main body, it is possible to easily provide a penetrating electrode with a large cross-sectional shape. The penetrating electrode is preferably an under bump metal portion and the outer terminal is preferably a bump. In this case, by utilizing the first protrusion, an under bump metal portion can be provided and the bump can be joined to the top of the under bump metal portion.

In another specific aspect of the electronic component according to a preferred embodiment of the present invention, the functional unit located on the substrate includes at least one IDT electrode and is a surface acoustic wave device. In this case, with a preferred embodiment of the present invention, it is possible to provide a surface acoustic wave device that has a reduced size and in which it is unlikely that leak defects will occur.

A method of manufacturing an electronic component according to a preferred embodiment of the present invention includes the following steps: a step of preparing a substrate on one main surface of which a functional unit is formed, a step of providing a heat-curable resin on the one main surface of the substrate so as to surround the functional unit on the one main surface of the substrate and so as to contain the frame-shaped supporting body main body, which is separated from the periphery of the substrate on the inner side, and the first and second protrusions, a step of stacking a lid member to form a frame-shaped heat-curable resin on the one main surface side of the substrate with the heat-curable resin therebetween, a step of completing the frame-shaped supporting body, and joining the frame-shaped supporting body, the one main surface of the substrate, and the lid member to one another by curing the heat-curable resin.

In a certain specific aspect of the method of manufacturing the electronic device according to a preferred embodiment of the present invention, the method further includes, after the step of completing the frame-shaped supporting body, a step of forming a through hole so as to penetrate through the first protrusion of the frame-shaped supporting body and the lid member, a step of forming a penetrating electrode in the through hole, and a step of joining an outer terminal to an upper end of the penetrating electrode. In this case, separate from the frame-shaped supporting body main body, a penetrating electrode can be formed by utilizing the first protrusion that the frame-shaped supporting body main body is provided with. Therefore, even if the thickness of the frame-shaped supporting body main body has only been thinned, the penetrating electrode can be easily formed. It is preferable that an under bump metal portion be formed as the penetrating electrode and a bump be formed as the outer terminal. In this case, an under bump metal portion can be formed by utilizing the first protrusion, and therefore the bump can be easily formed on top of the under bump metal portion.

In another specific aspect of the method of manufacturing the electronic component according to a preferred embodiment of the present invention, a surface acoustic wave substrate is prepared on which a surface acoustic wave element functional unit is formed as the substrate on which the functional unit is formed, and thus a surface acoustic wave device is provided. In this case, with a preferred embodiment of the present invention, it is possible to provide a surface acoustic wave device in which progress can be made in size reduction and in which it is unlikely that leak defects will occur.

According to an electronic component of various preferred embodiments of the present invention, at the time of forming the frame-shaped supporting body composed of a heat-curable resin, even if the frame-shaped supporting body becomes deformed due to curing shrinkage, since the second protrusion is provided at a portion at which the first protrusion is continuous with the supporting body main body, strain in the portion in which the first protrusion and the supporting body main body are continuous with each other can be suppressed or prevented. Consequently, the occurrence of gaps between the supporting body and the lid member can be suppressed or prevented and as a result, leak defects can be suppressed or prevented. Therefore, a compact electronic component can be provided in which leak defects are unlikely to occur and that is excellent in terms of environmental resistance.

The above and other elements, features, steps, characteristics and advantages of the present invention will become more apparent from the following detailed description of the preferred embodiments with reference to the attached drawings.

### BRIEF DESCRIPTION OF THE DRAWINGS

FIGS. 1A and 1B are a front sectional view of a surface acoustic wave device, which is an example of an electronic component according to a preferred embodiment of the present invention and a bottom view of the structure of a portion that will form a single surface acoustic wave device prior to being divided from a mother piezoelectric substrate and from which a lid member has been removed.

FIG. 2A is a plan view of a surface acoustic wave element used in a preferred embodiment of the present invention, and FIG. 2B is a schematic plan view in which electrode structures have been removed from the structure illustrated in FIG. 1B and illustrates only a frame-shaped supporting body.

FIGS. 3A to 3E are front sectional views for describing a method of manufacturing a surface acoustic wave device according to a preferred embodiment of the present invention.

FIGS. 4A to 4E are front sectional views for describing a method of manufacturing a surface acoustic wave device according to a preferred embodiment of the present invention.

FIG. 5 is a plan view illustrating a state in which electrodes of portions that will form a plurality of surface acoustic wave elements and frame-shaped supporting bodies have been formed on a mother wafer prepared using a manufacturing method of a preferred embodiment of the present invention.

FIG. 6 is a schematic plan view illustrating the directions of strain at the time of heat curing in a portion in which a frame-shaped supporting body and a first protrusion are continuous with each other.

FIG. 7 is a schematic plan view for describing the directions of strain in a first protrusion, a second protrusion and a frame-shaped supporting body main body in a portion in which a frame-shaped supporting body and the first protrusion are continuous with each other.

FIG. 8 is a schematic plan view illustrating only a frame-shaped supporting body of a surface acoustic wave device according to a modification of a preferred embodiment of the present invention.

FIG. 9 is a front sectional view illustrating an example of a surface acoustic wave device of the related art.

### DETAILED DESCRIPTION OF THE PREFERRED EMBODIMENTS

Hereafter, the present invention will be made clear by describing specific preferred embodiments of the present invention while referring to the drawings.

In the following preferred embodiments, a WLCSP type surface acoustic wave device, which is a non-limiting example of an electronic component, will be described.

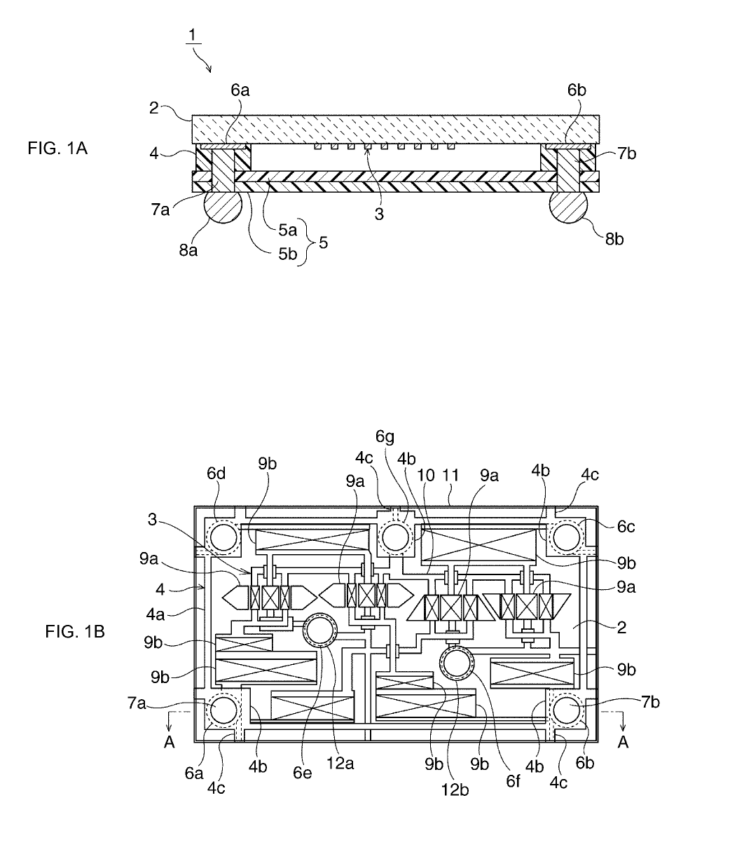

FIG. 1A is a front sectional view illustrating an electronic component 1 according to a preferred embodiment of the present invention. The electronic component 1 preferably is a WLCSP type surface acoustic wave device. The electronic component 1 includes a substrate 2. The substrate 2 preferably is a surface acoustic wave element substrate and includes a piezoelectric material. As such a piezoelectric material, a suitable piezoelectric material such as LiTaO₃, LiNbO₃, or quartz can be used, for example.

Functional units 3 are located on the lower surface of the substrate 2. The functional units 3, as will be described below, include IDT electrodes, reflectors, wiring and pad electrodes. Structures including metal materials and including such functional units include multilayer conductive films defined by Ti films and Al—Cu alloy films in the present preferred embodiment. However, the metal structures located on the substrate 2 may be made of other metal materials. That is, a suitable metal material such as Al, Cu, Ti, Pt, Au, Ag, Ni, Cr, Pd or an alloy containing at least one of these metals can be used, for example.

As illustrated in FIG. 1A, a frame-shaped supporting body 4 is joined to the lower surface of the substrate 2. The frame-shaped supporting body 4 preferably has a rectangular or substantially rectangular frame-shaped configuration. However, the frame-shaped supporting body 4 may have a frame-shaped configuration other than a rectangular or substantially rectangular frame-shaped configuration. The supporting body 4 is preferably composed of a cured material of heat-curable resin. In this preferred embodiment, a polyimide-based resin preferably is used as the heat-curable resin. However, the supporting body 4 may be formed using another heat-curable resin, for example.

The supporting body 4, as will be described below, is preferably arranged so as to surround the functional units 3. In addition, a lid member 5 is located on the lower end of the supporting body 4 so as to close the opening of the supporting body 4. The lid member 5 preferably has a structure formed by stacking a first layer 5a including an epoxy-based resin and a second layer 5b including a polyimide-based resin. However, the lid member 5 may be formed of a single material layer, for example. Furthermore, the lid member 5 can be formed of a suitable insulating material other than the above-mentioned resins, for example.

As illustrated in FIG. 1A, pad electrodes 6a and 6b are located on the lower surface of the substrate 2. Protrusions 4b and 4b, which will be described below, of the supporting body 4 are arranged so as to cover the pad electrodes 6a and 6b. In addition, in portions where the protrusions 4b and 4b of the supporting body 4 are provided, through holes are provided in the supporting body 4. These through holes penetrate through not only the supporting body 4 but also through the lid member 5.

Under bump metal portions 7a and 7b are provided as penetrating electrodes inside the through holes. The under bump metal portions 7a and 7b have structures defined by a Ni layer and an Au layer being stacked one on top of the other in this preferred embodiment. The materials that define the under bump metal portions 7a and 7b are not limited to the above-mentioned metals and suitable conductive materials similar to the materials that can be used to define the above-described metal structures can be used. In addition, the under bump metal portions 7a and 7b may include a single metal.

The upper ends of the under bump metal portions 7a and 7b are joined to the pad electrodes 6a and 6b. In addition, the lower ends of the under bump metal portions 7a and 7b are exposed at the lower surface of the lid member 5. Bumps 8a and 8b made of a Sn—Ag—Cu-based solder are arranged on the lower surface of the under bump metal portions 7a and 7b as outer terminals.

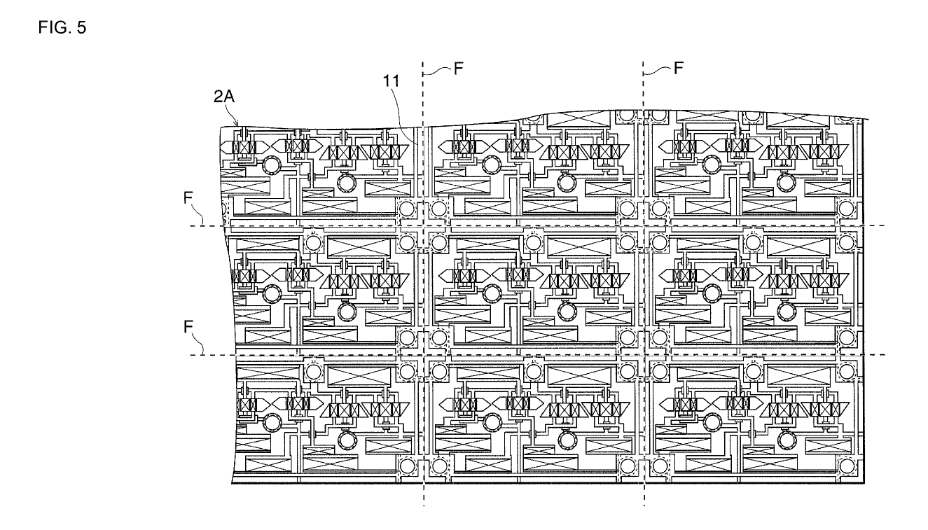

The planar shapes of the functional units 3, the supporting body 4, the under bump metal portions 7a and 7b and so forth of the electronic component 1 will be described with reference to FIG. 1B. The electronic component 1, as illustrated in FIG. 5, which will be referred to below, is obtained by forming the functional units and supporting bodies of a plurality of electronic components 1 on a mother substrate 2A and then dividing the mother substrate 2A.

FIG. 1B is a schematic bottom view of a portion of the mother substrate 2A that corresponds to a single electronic device 1. Here, a structure in which the lid member 5 and the bumps 8a and 8b illustrated in FIG. 1A are not provided is illustrated. In addition, a feeder line 11 is provided around the outer periphery of the lower surface of a single substrate 2 in FIG. 1B. The feeder line 11 is ultimately removed when the mother substrate 2A illustrated in FIG. 5 is divided. Alternatively, the feeder line 11 is not provided in the finally obtained electronic component 1 illustrated in FIG. 1A.

In addition, the front sectional structure illustrated in FIG. 1A is a front sectional view of the final electronic component 1 corresponding to the portion along the line A-A of FIG. 1B.

As illustrated in FIG. 1B, the feeder line 11 is provided along the outer periphery of the substrate 2. The feeder line 11 is preferably formed of the same metal as that with which the previously mentioned functional units 3 are formed. It is preferable that the feeder line 11 be formed of the same electrode material as the wiring and so forth included in the functional units 3. Thus, the feeder line 11 can be formed at the same time as the wiring and so forth.

Within a region surrounded by the feeder line 11, the rectangular or substantially rectangular frame-shaped supporting body 4 is provided. The supporting body 4 includes a rectangular or substantially rectangular frame-shaped supporting body main body 4a. In a region surrounded by the supporting body main body 4a, the above-mentioned functional units 3 are provided. In the functional units 3, in order to form a surface acoustic wave filter device, a plurality of longitudinally coupled resonator type surface acoustic wave filters 9a and one-port-type surface acoustic wave resonators 9b are provided.

The longitudinally coupled resonator type surface acoustic wave filters 9a and one-port-type surface acoustic wave resonators 9b are constructed by forming electrode structures such as IDT electrodes and reflectors on the substrate 2 in accordance with the functions thereof. The longitudinally coupled resonator type surface acoustic wave filters 9a and one-port-type surface acoustic wave resonators 9b are electrically connected to each other via wiring electrodes 10 and define functional units 3 as surface acoustic wave filter devices. In preferred embodiments of the present invention, the electrode structures of the functional units 3 are not particularly limited.

Pad electrodes 6a to 6g are provided to enable electrical connection to the outside so as to enable electrical connection to wiring electrodes 10 of the functional units 3. The pad electrodes 6a to 6g are indicated by broken lines in FIG. 1B. For example, as with the pad electrodes 6a and 6b, this is because the pad electrodes 6a and 6b are covered by the first protrusions 4b of the supporting body 4. In addition, as is clear from the portions where the pad electrodes 6a and 6b are provided, the under bump metal portions 7a and 7b are provided in the first protrusions 4b of the supporting body 4, which cover the pad electrodes 6a and 6b.

The first protrusions 4b of the supporting body 4 are located in portions where the pad electrodes 6a and 6b are provided as described above. More specifically, in portions in which the pad electrodes 6a, 6b, 6c, 6d and 6g, among the pad electrodes 6a to 6g, which are provided at positions along the outer periphery of the substrate 2, are disposed, the first protrusions 4b are provided so as to protrude toward the inside from the outer periphery of the supporting body main body 4a of the supporting body 4, that is, toward the inside of the opening surrounded by the supporting body 4. The first protrusions 4b are portions that cover the pad electrodes 6a to 6d, and 6g and form through holes to define the under bump metal portions 7a and 7b. Therefore, in this preferred embodiment, the first protrusions 4b preferably have a rectangular or substantially rectangular shape in plan view and are of a certain area.

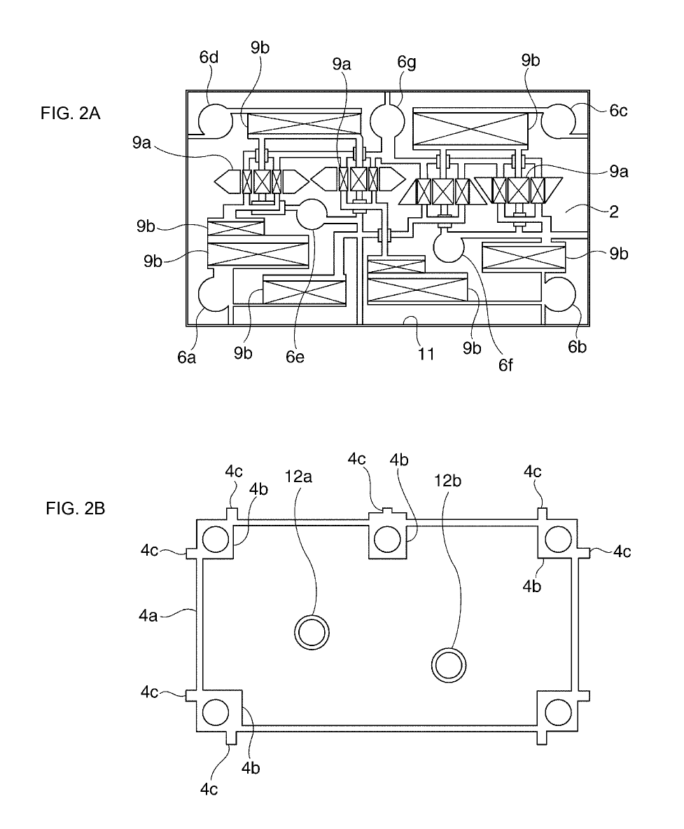

FIG. 2A is a plan view illustrating a state in which the supporting body 4, the under bump metal portions 7a and 7b and so forth have been removed from the structure illustrated in FIG. 1B. That is, FIG. 2A is a bottom view illustrating a structure in which the functional units 3, the pad electrodes 6a to 6g and the feeder line 11 located on the substrate 2 are formed. In addition, FIG. 2B is a plan view illustrating the supporting body 4 and supporting columns 12a and 12b, which include a heat curable resin and located on portions where the pad electrodes 6e and 6f are provided in FIG. 1B. The supporting columns 12a and 12b are located on portions where the pad electrodes 6e and 6f are provided and have a cylindrical or substantially cylindrical shape. In addition, through holes are provided in the supporting columns 12a and 12b. Under bump metal portions are provided inside the through holes.

A method has also been considered in which the first protrusions 4b are not provided, when forming the portions in which the under bump metal portions 7a and 7b are formed in the supporting body 4. That is, if the width of the supporting body 4, that is, the width of the supporting body main body 4a of the supporting body 4 is made large, the under bump metal portions can be provided at desired positions in the supporting body main body 4a. However, in this structure, the area of the opening surrounded by the supporting body main body 4a becomes smaller. Therefore, it becomes difficult to make progress in size reduction.

Consequently, as in this preferred embodiment, usually, the width of the supporting body main body 4a having a rectangular or substantially rectangular shape is made small and the first protrusions 4b are provided inside the supporting body main body 4a. Thus, the area of the portion surrounded by the supporting body main body 4a can be made large.

However, when the first protrusions 4b are provided, strain, or deformation is generated when the heat-curable resin of the supporting body 4 undergoes curing shrinkage. Due to this strain, there has been a risk of leak defects occurring.

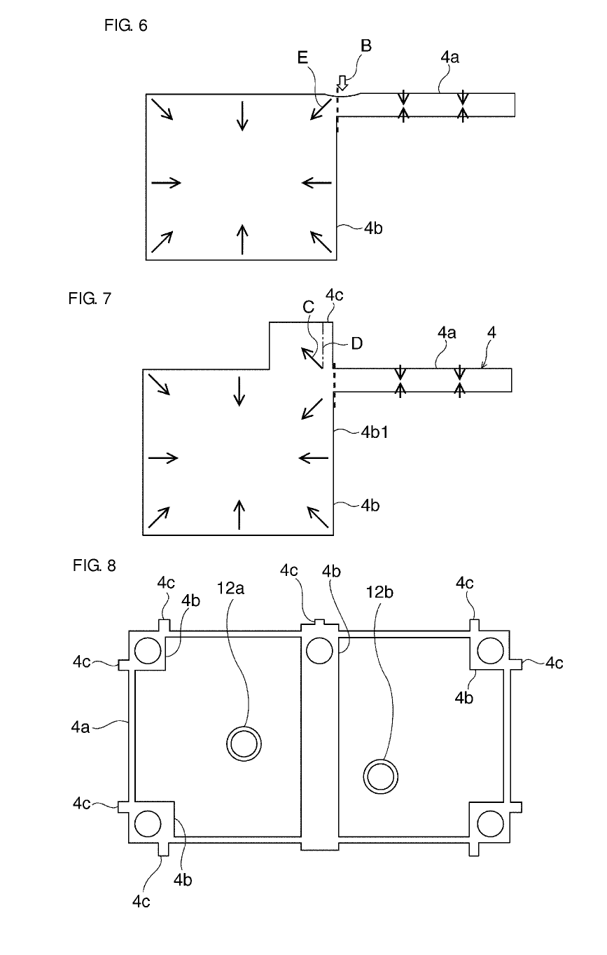

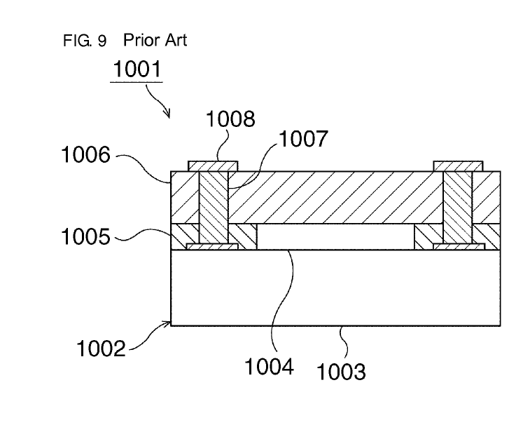

One of the unique features of this preferred embodiment is that second protrusions 4c are provided in addition to the first protrusions 4b in order to prevent the occurrence of leak defects. The second protrusions 4c are provided in portions in which the first protrusions 4b are provided in the supporting body 4, so as to extend from the supporting body main body 4a toward the side opposite to that of the first protrusions 4b, that is, toward the outside. Thus, the stress, or deformation generated during curing shrinkage in portions where the supporting body main body 4a and the first protrusions 4b are continuous with each other is reduced. Consequently, leak defects can be prevented. This point will be explained while referring to FIG. 6 and FIG. 7.

FIG. 6 is a schematic view of the structure of a comparative example in which the first protrusions 4b are continuous with the supporting body main body 4a and the second protrusions are not provided. In the case where the supporting body 4 is composed of a heat-curable resin and is heat cured, curing shrinkage occurs. The directions of stress at this time are indicated by arrows E in FIG. 6. The first protrusions 4b having a rectangular planar shape are deformed as the rectangular shape undergoes shrinkage. In addition, in the band-shaped supporting body main body 4a, curing shrinkage progresses such that the width thereof becomes smaller. Therefore, in portions where the supporting body main body 4a and the first protrusions 4b are continuous with each other, the outer periphery of the supporting body main body 4a attempts to shift toward the inside as indicated by the arrow B. Thus, strain and twisting occurs in the supporting body main body 4a. As a result, a gap is generated when the lid member 5 is joined to the supporting body 4 and therefore a leak defect occurs.

In contrast, as illustrated in FIG. 7, in a structure in which the second protrusions 4c are provided, shrinkage progresses in the directions indicated by the arrows C in the second protrusions 4c during curing shrinkage. Consequently, in portions in which the supporting body main body 4a and the first protrusions 4b are continuous with each other, it is unlikely that deformation of a kind indicated by the arrows B in FIG. 6 will occur. Consequently, leak defects can be prevented.

In FIG. 7, in portions in which the first protrusions 4b and the second protrusions 4c are continuous with each other, the second protrusions 4c face in a direction toward the outside with respect to the supporting body main body 4a, and the second protrusions 4c do not necessarily have to be exactly formed at the positions illustrated in FIG. 7. For example, one end portion of the second protrusion 4c, as illustrated by the one dot chain line D, may be shifted in a lateral direction from a position at which an edge 4b1 of the first protrusion 4b is continuous with the supporting body main body 4a. Also in such a case, strain is generated in a similar manner to stress illustrated by arrows C. Therefore, leak defects can be effectively prevented. Therefore, the second protrusions 4c may be provided so as to protrude toward the outside from the supporting body main body 4a in the vicinity of portions in which the first protrusions 4b are continuous with the supporting body main body 4a. In addition, so long as the shrinkage strain indicated by the arrows C can be caused to be generated, the planar shape of the second protrusions 4c is not limited to a shape such as a rectangle.

In this preferred embodiment, the width of the frame-shaped supporting body main body 4a preferably is about 20 μm, for example. The first protrusions 4b preferably have a square shape of approximately 116 μm×116 μm, for example. In addition, the protruding length of the second protrusions 4c preferably is about 30 μm or more, for example. The protruding length is the length of the second protrusions 4c in the direction in which the second protrusions 4c protrude from the outer periphery of the supporting body main body 4a toward the outside. In this preferred embodiment, the protruding length is the protruding length of the second protrusions 4c in portions orthogonal to the outer periphery of the supporting body main body 4a. However, the width of the supporting body main body 4a, and the dimensions of the first and second protrusions 4b and 4c are not particularly limited.

Of course, the area and the shape of the second protrusions 4c may be suitably set in accordance with the rate of curing shrinkage and the curing temperature of the heat-curable resin forming the supporting body 4.

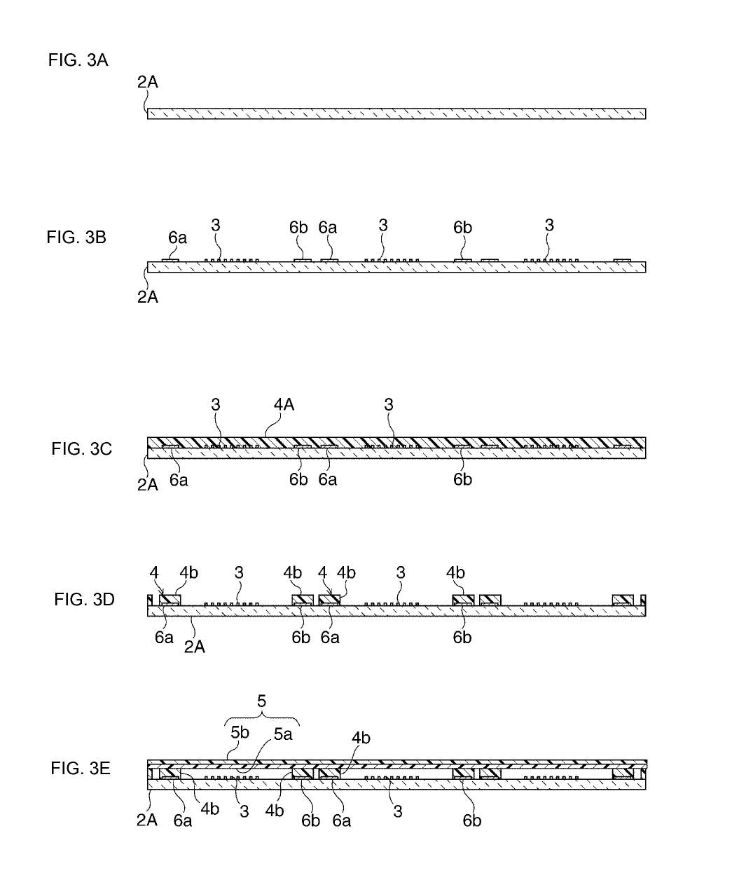

Next, a method of manufacturing the electronic component 1 of a preferred embodiment of the present invention will be described with reference to FIGS. 3A to 5.

As illustrated in FIG. 3A, first, the mother substrate 2A is prepared. Next, a plurality of the functional units 3, the pad electrodes 6a and 6b, and so forth, and, although not illustrated in FIG. 3B, the feeder line 11 is formed on the mother substrate 2A by using a thin film fine processing technology.

The feeder line 11 will be described below in detail.

Next, as illustrated in FIG. 3C, a photosensitive epoxy-based resin is applied so as to cover the entirety of the upper surface of the mother substrate 2A. Thus, an epoxy-based resin layer 4A is formed.

Next, as illustrated in FIG. 3D, the epoxy-based resin layer 4A is patterned using a photolithographic method. Thus, as illustrated in FIG. 3D, the supporting body 4 is formed. In FIG. 3D, portions in which the first protrusions 4b of the supporting body 4 are provided are illustrated, but the supporting body main body 4a, the second protrusions 4c, and the supporting columns 12a and 12b and so forth are also formed in the same process. Naturally, at this stage, the epoxy-based resin has not yet been cured with heat.

FIG. 5 is a plan view of the mother substrate 2A in a state where the process of FIG. 3D has been completed. The above-mentioned feeder line 11 will be described with reference to FIG. 5. The feeder line 11 is formed in a region in which a plurality of electronic components included in the mother substrate 2A are formed. In this preferred embodiment, a plurality of electronic components are formed in a matrix pattern. Therefore, the feeder line 11 preferably has a lattice-shaped configuration. The feeder line 11 is removed when a dicing process, which will be described below, is performed.

In addition, in order to reduce damage caused by a laser process, which will be described below, the thickness of the pad electrodes 6a to 6g is made to be larger than that of the other metal structures such as the IDT electrodes and wiring electrodes. Specifically, it is preferable that the thickness of the Al—Cu alloy be about 2.3 μm or more, for example.

Next, as illustrated in FIG. 3E, the first and second layers 5a and 5b of the lid member 5 are stacked one on top of the other by laminating a heat-curable resin using a lamination process. Thus, the opening surrounded by the supporting body 4 is closed.

At the time of lamination of the lid member 5, it is preferable that the first layer 5a be in a non-cured state and the second layer 5b be in a cured state in advance. The second layer 5b is cured with heat or light, and such that warping of the lid member 5 caused by the cured second layer 5b is suppressed or prevented.

Next, as illustrated in FIG. 3E, after the lamination process has been performed, the entire body is heated. Thus, the supporting body 4 and the first layer 5a are cured. As a result, the first layer 5a and the supporting body 4 are joined together and a cavity that the functional units 3 of the electronic component 1 face is formed. At the time of curing, as described above, the second protrusions 4c have been provided and therefore it is not likely that deformation will occur in portions where the first protrusions 4b and the supporting body main body 4a are continuous with each other. Therefore, it is possible to form a cavity that is excellent in terms of sealability and in which it is unlikely that a leak defect will occur.

The supporting body 4 and the first layer 5a are preferably cured in the same heat curing process. Consequently, the heat-curable resin forming the first layer 5a and the heat-curable resin forming the supporting body 4 are preferably resins that are cured in the same temperature range. More preferably, it is preferable that the first layer 5a and the supporting body 4 be formed of the same heat-curable resin. Thus, the supporting body 4 and the first layer 5a can be cured by being heated in the same temperature range and the heating process can be simplified. In addition, when the same resin is used, the strength of the bond between the first layer 5a and the supporting body 4 can be effectively increased.

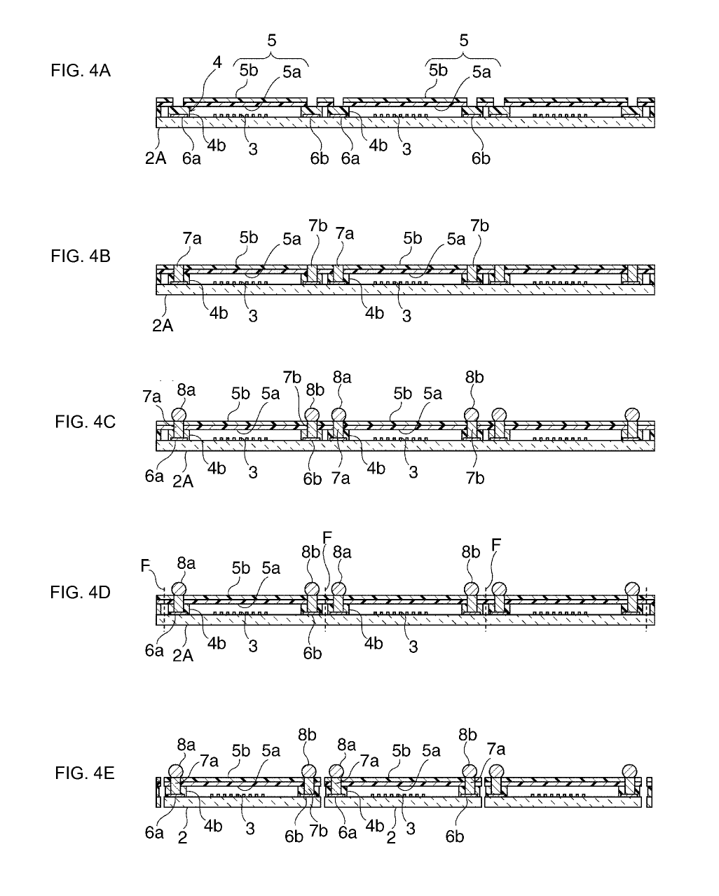

Next, as illustrated in FIG. 4A, through holes are formed so as to penetrate through the lid member 5 by using for example a laser process. In FIG. 4A, a state is illustrated in which through holes are formed so as to penetrate through the lid member 5, and furthermore the through holes are formed so as to also penetrate through the supporting body 4 by performing a laser process. Thus, the pad electrodes 6a and 6b are exposed through the through holes.

Next, as illustrated in FIG. 4B, the under bump metal portions 7a and 7b are formed in the through holes. When forming the under bump metal portions 7a and 7b, in this preferred embodiment, a Ni layer is formed in the through holes and then an Au layer is formed by electroplating.

Next, as illustrated in FIG. 4C, the bumps 8a and 8b, which are composed of solder and mentioned above, are formed on the under bump metal portions 7a and 7b.

Then, as illustrated in FIG. 4D and FIG. 5, cutting is performed along division lines F indicated by the broken lines by performing dicing or the like. As a result, as illustrated in FIG. 4E, the electronic component 1 can be obtained.

The above-described manufacturing method is just an example of a method of manufacturing the electronic component 1, and the electronic component 1 can be manufactured using another manufacturing method.

As described above, in the electronic component 1 of the present preferred embodiment, the second protrusions 4c are provided, and as a result it is unlikely that gaps will occur, which would cause leak defects, between the supporting body 4 and the lid member 5 and between the supporting body 4 and the substrate 2. The electronic component 1 of the above-described preferred embodiment and an electronic component of a comparative example formed in the same manner except that the second protrusions 4c were omitted from the structure of the present preferred embodiment were manufactured. The percentage of leak defects in electronic components of the preferred embodiment and the comparative example were measured in a gross leak test. The result of the test for the comparative example was 1.56%. In contrast, in the example of a preferred embodiment of the present invention, the percentage of leak defects was 0.03% and therefore the percentage of leak defects was able to be lowered by a significant amount.

In the present preferred embodiment, the first protrusions 4b are provided in order to form the under bump metal portions 7a and 7b, but may instead be provided in order to simply reinforce the supporting body main body 4a.

FIG. 8 is a schematic plan view of the frame-shaped supporting body 4 of a surface acoustic wave device according to a modification of a preferred embodiment of the present invention. FIG. 8 corresponds to FIG. 2B, which illustrates a preferred embodiment of the present invention.

This modification is the same as the preferred embodiment of the present invention shown in FIG. 2B except for the structure of the frame-shaped supporting body 4. Therefore, in FIG. 8, portions the same as those in FIG. 2B are denoted by the same reference symbols.

As illustrated in FIG. 8, in this modification, the first protrusions 4b are also provided inside the supporting body main body 4a at corner portions of the frame-shaped supporting body 4. Furthermore, in addition to the first protrusions 4b, the second protrusions 4c are provided. Thus, similarly to as in the case of the preferred embodiment illustrated in FIG. 2B, leak defects are prevented.

Furthermore, in this modification, a first protrusion 4b extends from one long edge of the supporting body main body 4a so as to reach another long edge on the opposite side in the center of the length direction of the frame-shaped supporting body 4. That is, the first protrusion 4b is arranged so as to partition the space between the two long edges of the supporting body main body 4a. Thus, a transmission filter can be provided on one side of the first protrusion 4b and a reception filter can be provided on the other side of the first protrusion 4b functioning as a partition. Thus, the first protrusion 4b may be arranged so as to function as a partition that partitions the frame-shaped supporting body 4.

In each of the above-described preferred embodiments, description has been given of a surface acoustic wave device, but the present invention is not limited to a surface acoustic wave device and can generally be applied to any electronic components having a sealed cavity.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. An electronic component comprising:
a substrate;
a functional unit located on one main surface of the substrate;
a frame-shaped supporting body including a heat-curable resin that is arranged on the one main surface of the substrate so as to surround the functional unit and so as to be separated from a periphery of the substrate on an inner side; and
a lid member that is fixed to the supporting body so as to seal an opening of the supporting body; wherein
the frame-shaped supporting body includes a frame-shaped supporting body main body, a first protrusion that protrudes toward an inside from the supporting body main body and a second protrusion that is provided at a portion in which the supporting body main body and the first protrusion are continuous with each other so as to protrude toward an outside from the supporting body main body.

3. The electronic component according to claim 2, further comprising a penetrating electrode that is electrically connected to the functional unit and penetrates through the first protrusion and the lid member, and an outer terminal that is connected to an upper portion of the penetrating electrode.

4. The electronic component according to claim 3, wherein the penetrating electrode includes an under bump metal portion and the outer terminal includes a bump.

5. The electronic component according to claim 2, wherein the functional unit located on the substrate includes at least one IDT electrode and is a surface acoustic wave device.

6. The electronic component according to claim 2, wherein the functional unit is a wafer level chip size packaging surface acoustic wave device.

7. The electronic component according to claim 2, further comprising additional functional units located on the one main surface of the substrate.

8. The electronic component according to claim 2, wherein the frame-shaped supporting body is rectangular or substantially rectangular.

9. The electronic component according to claim 2, further comprising pad electrodes located on the one main surface of the substrate and covered by the first and second protrusions.

10. The electronic component according to claim 4, wherein the under bump metal portion includes a Ni layer and an Au layer stacked on each other, or a single metal layer.

11. The electronic component according to claim 7, wherein the functional units include a plurality of longitudinally coupled resonator type surface acoustic wave filters and a plurality of one-port-type surface acoustic wave resonators.

12. The electronic component according to claim 2, wherein one end portion of the second protrusion is spaced in a lateral direction from a position at which an edge of the first protrusion is continuous with the supporting body main body.

13. The electronic component according to claim 2, wherein a plurality of the first protrusion is provided inside the supporting body main body at corner portions of the frame-shaped supporting body, and a plurality of the second protrusion is provided.

14. The electronic component according to claim 13, wherein the first protrusions and the second protrusions have a rectangular or substantially rectangular shape in plan view.

15. The electronic component according to claim 2, wherein the first protrusion extends from one long edge of the supporting body main body so as to reach another long edge on an opposite side in a central region in a length direction of the frame-shaped supporting body.

16. The electronic component according to claim 2, wherein the first protrusion is arranged so as to partition a space between two longitudinal edges of the supporting body main body.

17. The electronic component according to claim 16, further comprising a transmission filter on a first side of the first protrusion and a reception filter on a second side of the first protrusion.

18. An electronic component manufacturing method for manufacturing the electronic component according to claim 2, the method comprising:
a step of preparing the substrate, on the one main surface on which the functional unit is formed;
a step of providing the heat-curable resin on the one main surface of the substrate so as to surround the functional unit on the one main surface of the substrate and so as to contain the frame-shaped supporting body main body, which is separated from the periphery of the substrate on the inner side, and the first and second protrusions;
a step of stacking the lid member to form frame-shaped heat-curable resin on the one main surface side of the substrate with the heat-curable resin therebetween; and
a step of completing the frame-shaped supporting body, and joining the frame-shaped supporting body, the one main surface of the substrate, and the lid member to one another by curing the heat-curable resin.

19. The electronic component manufacturing method according to claim 18, further comprising, after the step of completing the frame-shaped supporting body, a step of forming a through hole that penetrates through the first protrusion of the frame-shaped supporting body and the lid member, a step of forming a penetrating electrode in the through hole, and a step of joining an outer terminal to an upper end of the penetrating electrode.

20. The electronic component manufacturing method according to claim 19, wherein an under bump metal portion is formed as the penetrating electrode and a bump is formed as the outer terminal.

21. The electronic component manufacturing method according to claim 18, wherein a surface acoustic wave substrate is prepared on which a surface acoustic wave element functional unit is formed as the substrate on which the functional unit is formed.
